(19) United States
(12) Patent Application Publication
(10) Pub. No.: US 2008/0094004 A1
(43) Pub. Date: Apr. 24, 2008

(54) Light-Generating Body

(75) Inventor: Bernd Ackermann, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/574,527

(22) PCT Filed: Sep. 1, 2005
(86) PCT No.: PCT/IB05/52870

§ 371 Date: Mar. 1, 2007

(30) Foreign Application Priority Data
Sep. 9, 2004 (EP) 04104348.0

(51) Int. Cl. H05B 35/00

(52) U.S. Cl. 315/294

(57) ABSTRACT

A light-generating body for emitting light of homogeneous intensity and color, having at least one organic light-emitting diode (22) that emits in a planar fashion in a first region of the spectrum, at least one non-organic light emitting diode (10,14) that emits in a conical shape in a second region of the spectrum, and an arrangement for mixing the light emitted by all the light-emitting diodes that includes a diffuser surface.

This invention relates to a light-generating body, comprising a plurality of light-emitting diodes having different emission wavelengths, and a light-mixing arrangement for emitting light of a homogeneous intensity and color.

Light-emitting diodes (LEDs) are generally divided into non-organic light-emitting diodes (nLEDs) and organic light-emitting diodes (OLEDs) by the nature of their luminescent layer. In non-organic luminescent layers, the wavelength emitted is determined by the energy gap of the semiconductor materials used. In organic luminescent layers, the wavelength is determined by the nature of the doping. By mixing the light from differently colored LEDs, it is possible to produce, for example, white light of great brightness whose color point can be adjusted. By controlling the intensity of emission of the individual LEDs separately, it is also possible for the light to be set to other colors in the visible spectrum as well as to white, and/or for the effects of ageing and temperature (i.e. changes in intensity) to be compensated for in the emission.

A light-generating body for producing mixed colors with a homogeneous distribution of intensity and color is difficult to construct from nLEDs which emit in a conical shape from one or more emitting surfaces in point form, particularly if limits have to be observed with regard to the overall depth. Document EP 03101926 describes a homogeneous planar light-generating body of this kind of small overall depth that was constructed using a large number of diodes and a complex reflector arrangement. An unrestricted variation in color that is desirable calls not only for the use of differently colored LEDs but also for the LEDs to be individually driven, and hence for an electronic complexity which rises with the number of diodes, and for the high costs which this involves. This problem is further accentuated by the poor light yield of nLEDs in the green region of the spectrum, and by the large number of green nLEDs that this makes it necessary to have. It is precisely in fields such as, for example, flat screens or room lighting that the component costs, overall depth, and efficiency of a homogeneous planar light-generating body whose color can be varied are an important consideration.

It is therefore an object of the present invention to provide an efficient and homogeneous light-generating body whose color can be varied which meets the requirements relating to component costs, overall depth, and efficiency.

This object is achieved by a light-generating body as claimed in claim 1, comprising at least one organic light-emitting diode that emits in a planar fashion in a first region of the spectrum, at least one non-organic light-emitting diode that emits in a conical shape in a second region of the spectrum, and an arrangement for mixing the light emitted by all the light-emitting diodes, which arrangement includes a diffuser surface. Advantageous embodiments are specified in the dependent claims.

Light-generating bodies that emit mixed homogeneous white light by means of differently colored LEDs generally comprise a plurality of colored LEDs whose emitted colored light mixes, in a volume of space between the LEDs and the diffuser surface, to give white light. To allow a homogeneous perceived color and brightness to be obtained, all the light sources mentioned have a diffuser surface to scatter the light. In the case of non-organic LEDs, the emission area may be referred to as “of point form”. The term “of point form” is not to be understood in the mathematical sense of a point in this case but refers to an emitting area that is very small in relation to the area of the diffuser surface. In contrast to “of point form”, “planar” refers to an emission area that is very much larger. In the case of organic LEDs, an area of this kind may cover a few square centimeters or more. The organic LEDs emit in a planar fashion and thus, unlike nLEDs (whose emission is in the form of a cone), illuminate the diffuser surface homogeneously with any further steps being taken. The advantage of a combination according to the invention of light-emitting diodes that emit in a conical shape and in a planar fashion is the smaller overall depth which becomes possible for the arrangement for mixing light homogeneously. If the spacing between the non-organic LEDs is constant, if the differently colored nLEDs are symmetrically distributed and if the number of different colors of the nLEDs is quite small, then what is obtained is an overlap between the cones of light from adjoining nLEDs of the same color, at a shorter distance from the emitting surface than would be the case if there were a larger number of differently colored nLEDs.

In another embodiment, the use of organic LEDs whose maximum emission is in the green region of the spectrum is advantageous because it is precisely in this region of the spectrum that non-organic LEDs are of very low efficiency in respect of light yield and precisely in this region of the spectrum that organic LEDs emit very efficiently. In this way, the same intensity can be obtained in the green region of the spectrum with substantially fewer organic LEDs as compared with non-organic LEDs. By having a reduced number of LEDs, the component costs of the light-generating body can be reduced and energy can be saved.

In principle, white light can be mixed by using two light-emitting diodes that emit in different regions of the spectrum. The third spectral color that is missing for the production of white light can be added in this case by means of a partly transparent phosphor coating on a light-emitting diode that emits at short wavelengths, and by means of the partial conversion that is thereby obtained of the short-wavelength light into light of a longer wavelength. If there is a requirement for color mixes of any desired kind to be set, then recourse must be had not only to light-emitting diodes emitting in the first and second regions of the spectrum but also to a further light-emitting diode that emits in a third region of the spectrum.

For the emission of light that is variable in color and over time, it is advantageous if there are a first, a second and a third supply voltage for the light-emitting diodes that respectively emit in the first, second and third regions of the spectrum, which voltages can be set independently of one another. The amplitude and/or the variation over time of the current through the light-emitting diodes is modulated by means of these supply voltages.

For the production of colors in as large a part as possible of the color space, it is also advantageous if the maximum emission of the light-emitting diode that emits in the second region of the spectrum is in the red region of the spectrum and if the maximum emission of the light-emitting diode that emits in the third region of the spectrum is in the blue region of the spectrum. Particularly effective non-organic LEDs are available for the red and blue regions of the spectrum.

When homogeneous white light is being generated, it is possible, by the use of efficient green organic LEDs, for the number of green LEDs to be almost halved as compared with an arrangement having non-organic green LEDs. Homogeneous white light can thus be produced with a very similar number of red, green and blue LEDs. As well as the reduction which has already been pointed out in the number of components, it is also possible for the first, second and third supply voltages to be better balanced in this way, which in turn brings down the cost of the driving electronics and results in greater reliability.

To produce white light having a high color rendering index, what is required is at least one further light-emitting diode that emits in a fourth region of the spectrum. In line with the number of regions of the spectrum that are used, so do further supply voltages that can be set independently of one another have to be made available. Use may for example be made, in addition, of organic LEDs that emit in the blue-green region of the spectrum and of non-organic LEDs that emit in the yellow region of the spectrum. In this case too, homogeneous white light can be produced with very similar numbers of LEDs in the different regions of the spectrum, by using organic LEDs in the green and adjoining regions of the spectrum and non-organic LEDs in the red or blue and adjoining regions of the spectrum. In this way, advantages are once again obtained in respect of small numbers of components and well-balanced supply voltages.

With arrangements for mixing the light emitted by all the light-emitting diodes having an additional reflector arrangement for distributing the light in space, it is possible, by means of the combination according to the invention of light-emitting diodes that emit in a conical shape and in a planar fashion, for a saving to be made at least of the reflector arrangement for the organic light-emitting diodes that emit in a planar fashion, and for the cost of the reflector arrangement as a whole to be reduced in this way.

In an arrangement for mixing the light emitted by all the light-emitting diodes that includes a light-guide panel having a top and a bottom face and a plurality of side faces, the light from organic LEDs that emit in a planar fashion can be coupled in via the top and/or bottom faces, whereas the light from the nLEDs can be coupled in via at least one side face. In this case too, the number of LEDs required can be reduced by replacing nLEDs with organic LEDs that emit in a planar fashion, particularly when use is made of green organic LEDs. The light that is coupled in is mixed by reflection within the light-guide panel and is coupled out again by scattering perpendicularly to the surface of the light-guide panel.

In another embodiment, a light-generating body that emits over a very large solid angle by means of a curved diffuser surface that is closed in space, and in which the arrangement of light-emitting diodes according to the invention is arranged inside the diffuser surface, can be produced in a more compact form.

These and other aspects of the invention are apparent from and will be elucidated with reference to the embodiments described hereinafter.

In the drawings:

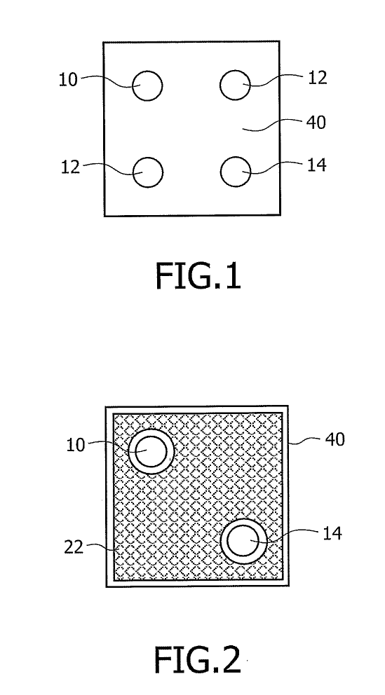

FIG. 1 is a plan view of a typical arrangement of non-organic LEDs on a printed-circuit board, for producing white light.

FIG. 2 is a plan view of an arrangement according to the invention of organic and non-organic LEDs on a printed-circuit board, for producing white light.

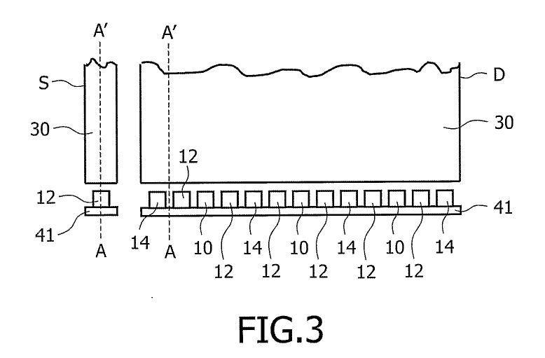

FIG. 3 is a plan view (D) and a side view (S) of an arrangement of non-organic LEDs for coupling light into a light-guide panel.

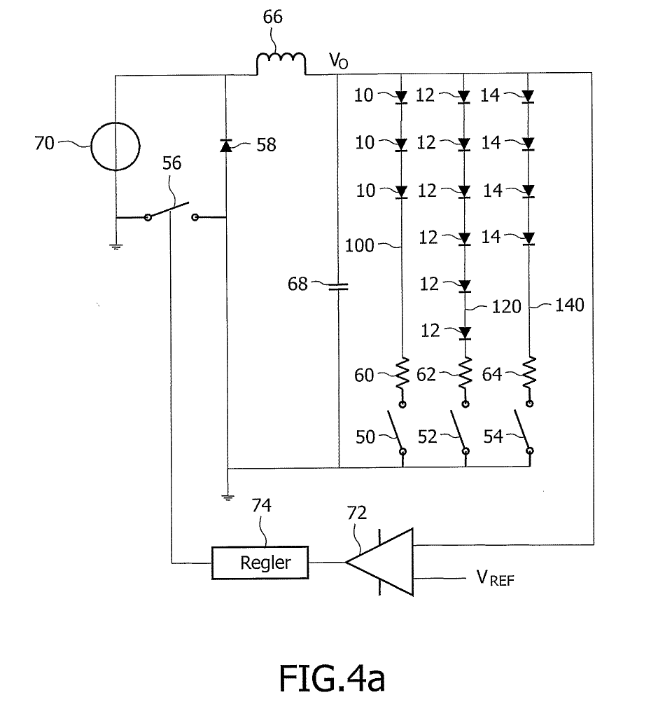

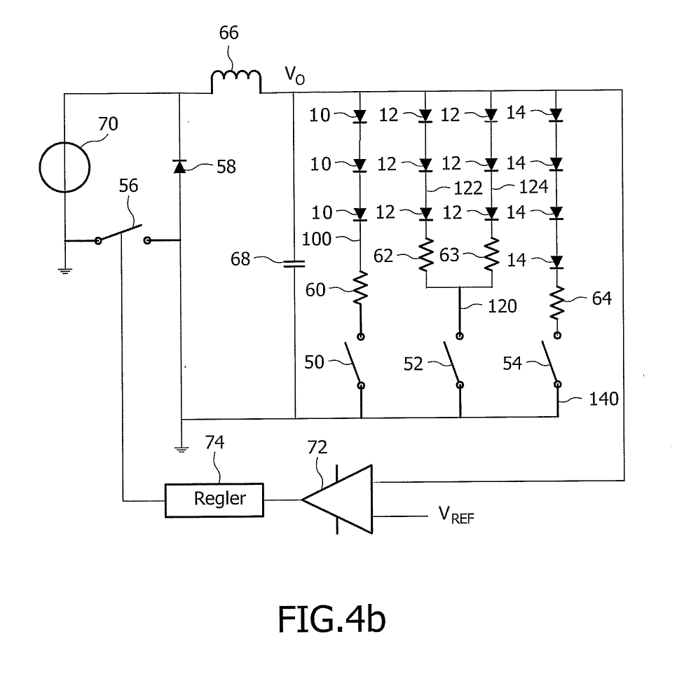

FIG. 4a is an electronic circuit diagram of an LED arrangement as shown in FIG. 3, in which there are different voltage drops on the three supply lines for red, green and blue.

FIG. 4b is an electronic circuit diagram of an LED arrangement as shown in FIG. 3, in which there are different currents on the three supply lines for red, green and blue.

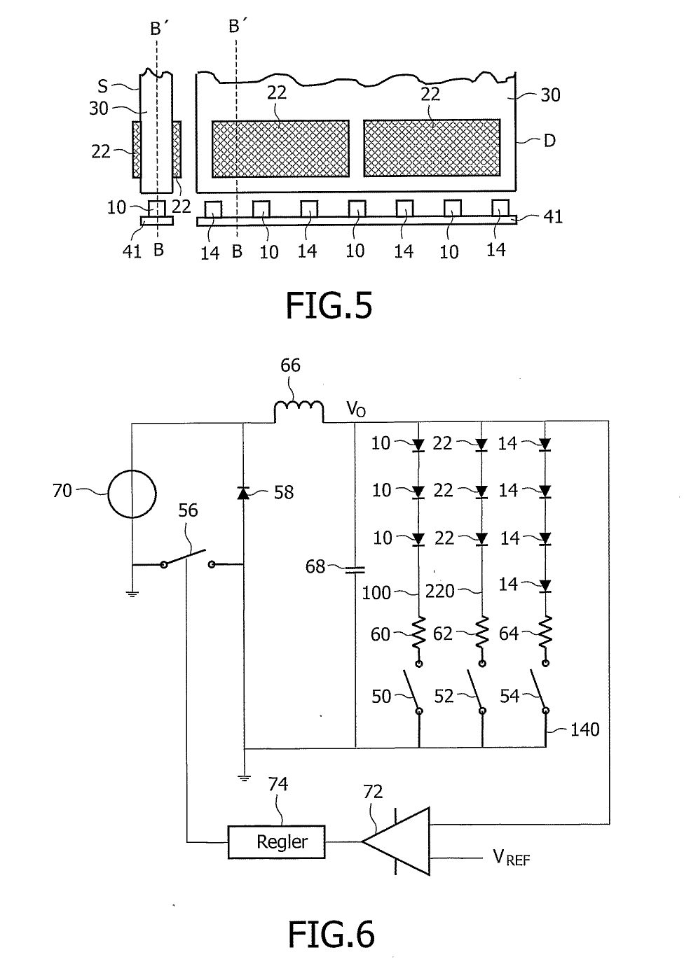

FIG. 5 is a plan view (D) and a side view (S) of an arrangement according to the invention of organic and non-organic LEDs for coupling light into a light-guide panel.

FIG. 6 is an electronic circuit diagram of an LED arrangement according to the invention as shown in FIG. 5.

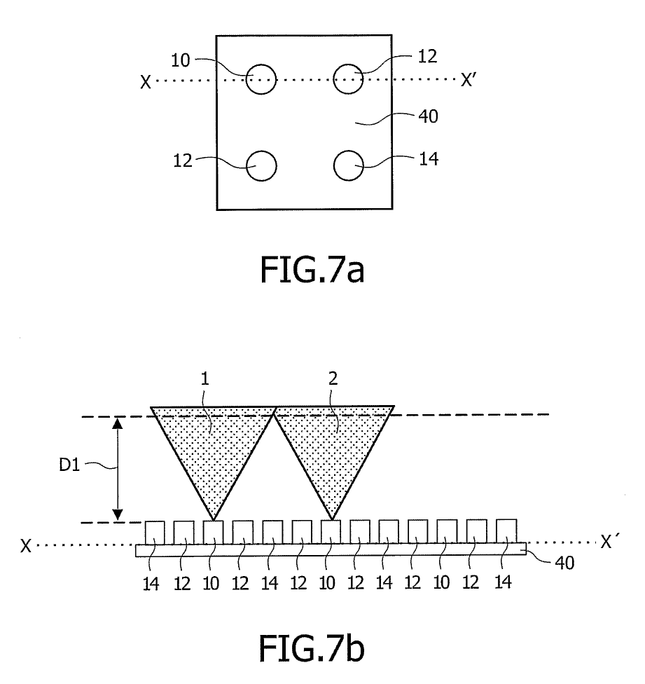

FIG. 7a is a plan view of a typical arrangement, as shown in FIG. 1, of non-organic LEDs on a printed-circuit board, for producing white light, with a plane of section X-X′ shown in the drawing.

FIG. 7b is a side view of FIG. 7a, on the plane of section X-X′.

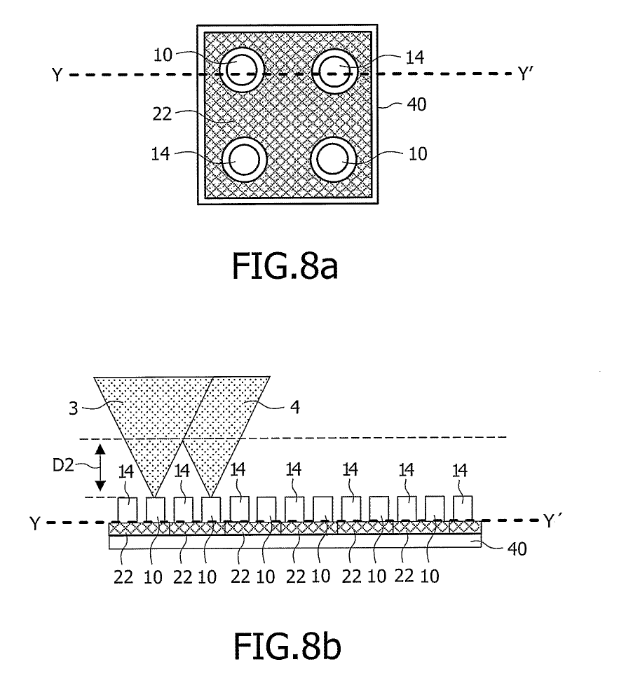

FIG. 8a is a plan view of an arrangement according to the invention of organic and non-organic LEDs on a printed-circuit board, for producing white light, the number of non-organic LEDs being the same as in FIG. 7a and a plane of section Y-Y′ being shown in the drawing.

FIG. 8b is a side view of FIG. 8a on the plane of section Y-Y′, and

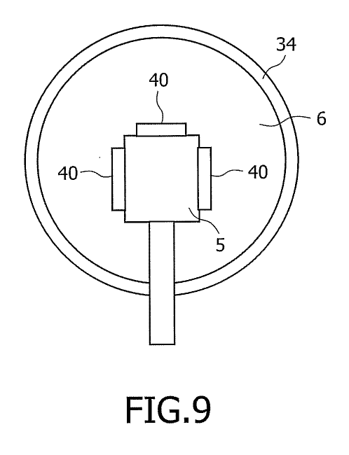

FIG. 9 shows a light-generating body for producing homogeneous white light over a large solid angle, having an arrangement of organic and non-organic LEDs as shown in FIG. 2 and a diffuser surface.

FIG. 1 is a plan view of a typical arrangement of red 10, green 12 and blue 14 non-organic LEDs for producing light of homogeneous intensity and color, on a printed-circuit board 40 that is used for driving the nLEDs 10, 12 and 14 electrically. Light of homogeneous intensity and color is produced by means of an arrangement (not shown here) for mixing the light emitted by all the light-emitting diodes. The construction of this mixer arrangement may be carried out in different ways, as will be described in detail below. Due to the low efficiency of green non-organic LEDs, twice as many green LEDs 12 as red LEDs 10 or blue LEDs 14 are required to produce white light with an acceptable luminance.

FIG. 2 is a plan view of an arrangement according to the invention of red 10 and blue 14 non-organic LEDs of point form and of a green organic LED of a planar type, on a printed-circuit board 40 that is used to drive the LEDs 10, 14 and 22 electrically. Seen in plan, the non-organic LEDs 10 and 14 are surrounded by the organic LED 22. The term “surrounded” refers in this case only to the projected position in the plan view. Seen from the side, the non-organic LEDs may be arranged, in the direction of emission, below the organic LED, on the same level as it, or above it. If the nLEDs are arranged above the organic LED 22, the organic LED 22 may also comprise a continuous surface of a specific thickness with no cut-outs at the projected positions of the nLEDs. A comparison of the arrangements shown in FIG. 1 and FIG. 2 reveals substantial advantages that the arrangement according to the invention has. On the one hand, for the same luminance, the number of LEDs can be reduced from four (FIG. 1: 1×red, 2×green, 1×blue) to three (FIG. 2: 1×red, 1×green, 1×blue) by the use of efficient green organic LEDs, and the component costs can be reduced in a corresponding way. An arrangement as shown in FIG. 2 contains equal numbers of differently colored organic and non-organic LEDs (one green, one red and one blue). This has advantages for the simplification of the electronic driving system, as a result of better balancing of the supply voltages applied when the green LEDs 12 in FIG. 1 are connected in series, and better balancing of the supply currents when the said green LEDs 12 are connected in parallel. The arrangement in space shown in FIG. 2 for the red 10 and blue 14 non-organic LEDs relative to the green organic LED is merely an example and is not intended to limit the invention to this geometry. Similarly, the green organic LED 22 may be not only of the square outside shape shown but also of other shapes. It would also be possible for the green organic LED 22 to be constructed from a plurality of electrically connected sub-LEDs having the same emissive properties, which together formed one organic LED that emitted in a planar fashion.

In FIG. 3, a typical embodiment of planar light-generating body for background lighting in flat screens is shown in a plan view D and in a side view S on the plane of section A-A′. In this case, the arrangement for mixing the light emitted by all the light-emitting diodes comprises, in addition, a light-guide panel 30 having a top face, a bottom face and a plurality of side faces, into which side faces the light from the red 10, green 12 and blue 14 non-organic light-emitting diodes that are mounted on a printed-circuit board 41 is coupled. For the homogeneous emission of white light, the light coupled in is coupled out in the direction of the diffuser surface (not shown in FIG. 3) by means of scattering centers in the light-guide panel, perpendicularly to the direction of coupling-in. As in the embodiment shown in FIG. 1, so too in this case the number of green non-organic light-emitting diodes 12 is, due to their low efficiency, twice as high as the number of red nLEDs 10 and blue nLEDs 14.

FIG. 4a is a circuit diagram of the arrangement shown in FIG. 3, in which there is a supply voltage 70 and three supply lines 100, 120 and 140 for the three sets of differently colored nLEDs. All the LEDs that emit in the same region of the spectrum are connected in series in this case, which means that the same current flows through them and they emit the same amount of light. The switch 56, the diode 58, the inductor 66 and the capacitor 68 form a reducer. As a result of suitable actuation of the switch 56, the controller 74 sets the output voltage V_{O} from the reducer to a reference value V_{REF}, with which the output voltage is compared in a comparator 72. By the switches 50, 52 and 54, the currents on the supply lines 100, 120 and 140 respectively are modulated over time. The resistors 60, 62 and 64 determine the amplitude of the currents on the supply lines 100, 120 and 140 respectively when the switch 50, 52 or 54 is switched on. Because of the large difference between the numbers of red 10, green 12 and blue 14 nLEDs, the controlling electronics has to cope with widely differing voltage drops on the three supply lines for the red, green and blue nLEDs. This makes greater demands on the electronics than would be the case if there were very similar voltage drops on all the supply lines, which becomes apparent in a negative way in the production costs and reliability of the driving system. The voltage drops on the three supply lines 100, 120 and 140 can be matched to one another by the connection in parallel of some of the green nLEDs 12 (supply lines 122 and 124), as shown in FIG. 4b. The total current for the green nLEDs that then flows through the supply line 120 has, however, to be larger in order to keep the current flowing through the individual green nLEDs constant. As a result however, the currents through the three supply lines become very different, which results in disadvantages comparable to those that exist with widely differing voltage drops. Also, the two resistors 62 and 63 have to be relatively large so that the current through the supply line 120 is distributed with sufficient evenness onto the parallel supply lines 122 and 124. The circuit diagrams shown in FIGS. 4a and 4b represent embodiments of an LED driver system. As well as these circuit diagrams there are also other variants that are possible, but these too suffer from the problems described.

The embodiment shown in FIG. 5 for the background lighting of flat screens is a plan view D and a side view S in the plane of section B-B′ of an arrangement according to the invention for mixing the light emitted by non-organic LEDs 10 and 14 and planar organic LEDs 22. In this case the light from red 10 and blue 14 non-organic LEDs, mounted on a printed-circuit board 41, is coupled in laterally as in FIG. 3. Compared with FIG. 3, all the green non-organic LEDs have been removed but the position and number of the red and blue LEDs have not been changed. The green light is coupled in from the top and bottom in this case (see also the side view in plane of section B-B′ in FIG. 5) by organic LEDs 22 that emit in a planar fashion. Similarly, as was previously the case with FIG. 2, the arrangement shown represents only one possible embodiment and is not to be construed as limiting with regard to the shape, position or number of the LEDs.

The greater efficiency of the green organic LEDs makes it possible for there to be a number of green organic LEDs 22 that is matched to the number of red 10 and blue 14 LEDs. The arrangement according to the invention that is shown in FIG. 5 can be operated by an LED driver system as shown in FIG. 6. With the very similar numbers of differently colored LEDs that become possible in this way, a better balance can be achieved between the voltage drops on the three supply lines 100, 220 and 140, which reduces the demands on the controlling electronics in comparison with the driver systems shown in FIGS. 4a and 4b, and thus reduces the component costs too and improves the reliability of the driver system.

A typical arrangement of non-organic LEDs for producing homogeneous white light is shown in FIG. 7a, which corresponds to FIG. 1 but with an additional plane of section X-X′ shown. FIG. 7b is a side-view on plane of section X-X′ showing two cones of light 1 and 2 emitted by two adjacent red LEDs 10. A homogeneous mixture of the light emitted by adjacent red, green and blue LEDs exists if the cones of light from adjacent LEDs of the same color begin to overlap. The distance from the LEDs, from which complete intermixing is obtained with any additional reflector arrangements incorporated in the light path is indicated in FIG. 7b as D1.

A corresponding arrangement according to the invention for producing homogeneous white light is shown in FIG. 8a. In this case, in comparison with FIG. 7a, the green non-organic LEDs 12 have been replaced by a red and a blue non-organic LED and are surrounded by a planar green organic LED 22. As in FIG. 2, so in the present case too does the term “surrounded” relate only to the projection of the non-organic LEDs in plan. Seen from the side, the non-organic LEDs may be situated above, on the same level as or below the organic LED 22, looking in the direction of emission. If the nLEDs are arranged above the organic LED 22, the organic LED 22 may also comprise a continuous area of a specific thickness with no cut-outs at the projected positions of the nLEDs. FIG. 8b is a side view of the arrangement shown in FIG. 8a on the plane of section Y-Y′. Because of the replacement of the green non-organic LEDs 12 by red or blue nLEDs, the red 10 and blue 14 non-organic LEDs that emit in a conical shape are positioned closer to one another. As a result, the overlap of the cones of light 3 and 4 from non-organic LEDs of the same color begins (homogeneous color mix achieved) at a distance D2 that is considerably smaller than D1. With an arrangement according to the invention of non-organic and organic LEDs as shown in FIGS. 8a and 8b, the overall depth of a planar light-source for emitting homogeneous light can be appreciably reduced. Complicated reflector arrangements as described in patent application EP 03101926 for reducing the overall depth of planar, homogeneously emitting light-sources, in which arrangements there is lateral deflection of the light from non-organic LEDs emitting in point form for the mixing of light by means of multiple reflections at mirrored side-walls, can be dispensed with completely or at least for the organic LED that emits in a planar fashion.

Another embodiment according to the invention is shown in FIG. 9. In this case, non-organic light-emitting diodes that emit in a conical shape and organic light-emitting diodes that emit in a planar fashion are arranged on printed-circuit boards 40 in the way shown in FIG. 2 and/or FIG. 8a, which printed-circuits boards 40 are mounted in turn in different directions in space on a carrier 5. In a volume of space 6, the colored light coming from all the light-emitting diodes mixes to form white light. The diffuser surface 34, which is mounted at the distance required for a homogeneous mixture of light, causes light of a homogeneous intensity to be emitted over a large solid angle. The arrangement according to the invention of the organic and non-organic light-emitting diodes, as shown in FIG. 2 and FIG. 8a, makes possible an advantageous, more compact construction and a smaller diameter for the diffuser surface 34. The spherical shape that is shown for the diffuser surface in FIG. 9 is merely an example and in other embodiments it may also assume other curved and physically continuous shapes.

The production of non-organic and planar organic LEDs is known to the person skilled in the art. Known techniques such as, for example, sputtering, vapor deposition and printing may be used to produce the organic LEDs structured as shown in FIG. 2 and/or FIG. 8a that have cut-outs at the points intended for fitting with non-organic LEDs. For these production processes for thin layers, use may be made not only of unstructured substrates but also of, for example, substrates that have holes at the points intended for fitting with non-organic LEDs. The structuring of the layered structure of an organic LED can be achieved by coating processes employing masks, by lithographic and etching processes and by printing processes.

The embodiments that have been elucidated only represent possible examples of a light-generating body and are not to be construed as limiting the invention to these examples.

1. A light-generating body for emitting light of a homogeneous intensity and color, having
at least one organic light-emitting diode (22) that emits in a planar fashion in a first region of the spectrum
at least one non-organic light-emitting diode (10, 14) that emits in a conical shape (1, 2, 3, 4) in a second region of the spectrum, and
an arrangement for mixing the light emitted by all the diodes that includes a diffuser surface.

2. A light-generating body as claimed in claim 1, characterized in that the maximum emission of the organic light-emitting diode (22) that emits in a planar fashion in a first region of the spectrum is in the green region of the spectrum.

3. A light-generating body as claimed in claim 1, characterized in that the light-generating body also comprises at least one non-organic or organic light-emitting diode that emits in a third region of the spectrum.

4. A light-generating body as claimed in claim 3, characterized in that a first, a second and a third supply voltage for the light-emitting diodes that respectively emit in the first, second and third regions of the spectrum can be set independently of one another, to enable the color of the light emitted by the light-generating body to be varied.

5. A light-generating body as claimed in claim 3, characterized in that the maximum emission of the light-emitting diode that emits in the second region of the spectrum is in the red region of the spectrum, and the maximum emission of the light-emitting diode that emits in the third region of the spectrum is in the blue region of the spectrum.

6. A light-generating body as claimed in claim 5, characterized in that the numbers of light-emitting diodes (10, 22, 14) that emit in the first, second and third regions of the spectrum are substantially the same.

7. A light-generating body as claimed in claim 3, characterized in that the light-generating body comprises a further non-organic or organic light-emitting diode that emits in at least one further region of the spectrum.

8. A light-generating body as claimed in claim 7, characterized in that at least one further supply voltage for the light-emitting diodes that emit in at least one further region of the spectrum can be set independently of the other supply voltages, to enable the color of the light, having a high color-rendering index, that is emitted by the light-generating body to be varied.

9. A light-generating body as claimed in claim 1, characterized in that the organic light-emitting diode (22) that emits in the first region of the spectrum is intended to irradiate the diffuser surface directly, and the arrangement for mixing the light emitted by all the light-emitting diodes includes a reflector arrangement between the non-organic LED and the diffuser surface, which reflector arrangement is intended to distribute, in space, the light that is emitted in a conical shape (1, 2, 3, 4) by the non-organic light-emitting diodes (10, 14).

10. A light-generating body as claimed in claim 1, characterized in that the arrangement for mixing the light emitted by all the light-emitting diodes includes a light-guide panel (30) having a top face, a bottom face and a plurality of lateral faces that are intended for coupling in, distributing and coupling out light, the light from the non-organic light-emitting diodes (10, 14) being coupled in by at least one lateral face and the light from the organic light-emitting diodes (22) being coupled in by the top and/or bottom face.

11. A light-generating body as claimed in claim 1, characterized in that the arrangement for mixing the light emitted by all the diodes comprises a physically continuous diffuser surface (34) that is, in itself, curved, and the light-emitting diodes arranged inside the diffuser surface are intended to illuminate a large solid angle.
